(19) United States
(12) Patent Application Publication
(10) Pub. No.: US 2024/0172565 A1
(43) Pub. Date: May 23, 2024

(54) MATERIALS GENERATING MULTI SPIN COMPONENTS FOR MAGNETIZATION SWITCHING AND DYNAMICS

(71) Applicant: Regents of the University of Minnesota, Minneapolis, MN (US)

(72) Inventors: Jian-Ping Wang, Shoreview, MN (US); Tony Low, Woodbury, MN (US); Yifei Yang, Minneapolis, MN (US); Seungjun Lee, Saint Paul, MN (US)

(21) Appl. No.: 18/496,019

(22) Filed: Oct. 27, 2023

Related U.S. Application Data
(60) Provisional application No. 63/382,377, filed on Nov. 4, 2022.

(51) Int. Cl. H10N 50/20; H10B 61/00; H10N 50/01; H10N 50/85

(52) U.S. Cl. CPC H10N 50/20; H10B 61/00; H10N 50/01; H10N 50/85

(57) ABSTRACT

A device which includes a free layer and a current channel. The free layer has a configurable magnetization state. The current channel includes a low-symmetry crystal with only one mirror plane. The low-symmetry material has relatively large unconventional spin Hall effect (SHE). A current through the current channel applies a spin-orbit torque that sets the magnetization state of the free layer.

This application claims the benefit of U.S. Provisional Patent Application No. 63/382,377, filed Nov. 4, 2022, the entire contents of which is incorporated herein by reference.

### GOVERNMENT INTEREST

This invention was made with government support under 70NANB17H041 awarded by the National Institute of Standards and Technology. The government has certain rights in the invention.

### BACKGROUND

With the advent of mobile and handheld electronic devices, the demand for much smaller, faster and ultra-low power systems keeps growing. The increasing density of complementary memories has caused significant increases in static and dynamic power consumption in electronic devices.

### SUMMARY

In general, the present disclosure describes devices that include spintronic devices whose magnetization state can be set with current through a current channel. The disclosure describes examples of materials for current channels, as one non-limiting example, where current through the current channel sets a magnetization state of a free layer coupled to the current channel.

The material for the current channel may include low-symmetry crystal materials having only one mirror plane. Such materials may generate unconventional spin Hall effects, suitable for applications including, but not limited to, a current channel. For instance, in such materials with low-symmetry having only one mirror plane, current through the current channel causes an unconventional spin-orbit torque (SOT) that sets the magnetization state of the free layer, and tends to require less amount of current, as compared to other materials for setting the magnetization state. In some examples, the low-symmetry crystal material may include Ni₄W or Ni₄Mo. Inclusion of these low-symmetry crystals which have only one mirror plane as the spin source material of the current channel may allow for efficient switching of perpendicular magnetization without an external field. Thus, the switching current may be reduced, and the power consumption of the device may be reduced. In some examples, the power consumption of devices which include low-symmetry crystals having only one mirror plane may be an order of magnitude lower than similar devices which do not include such low-symmetry crystals as the spin source material.

In some examples, the disclosure is directed to a device which includes a free layer and a current channel. The free layer has a configurable magnetization state. The current channel includes a low-symmetry crystal with only one mirror plane. The low-symmetry crystal has relatively large unconventional spin Hall effect (SHE). The device is configured such that a current through the current channel applies a spin-orbit torque that sets the magnetization state of the free layer.

In some examples, the disclosure is directed to a technique which includes forming a free layer having a configurable magnetization state. The technique also includes forming a current channel comprising a low-symmetry crystal with only one mirror plane having relatively large unconventional Spin Hall Effect (SHE). A current through the current channel applies a spin-orbit torque that sets the magnetization state of the free layer.

In some examples, the disclosure is directed to a device which includes free layer and a current channel. The free layer has a configurable magnetization state. The current channel includes a low-symmetry crystal which includes Ni₄W or Ni₄Mo. The device is configured such that a current through the current channel applies a spin-orbit torque that sets the magnetization state of the free layer.

In some examples, the disclosure is directed to a spin-orbit torque (SOT) MRAM device comprising a bitcell. The bitcell comprises a tunnel barrier and a current channel adjacent to the tunnel barrier. The current channel comprises a low-symmetry crystal with only one mirror plane

In some examples, the disclosure is directed to a device which includes a free layer and a current channel. The free layer has a configurable magnetization state. The current channel includes a low-symmetry crystal with a space group, and the space group is one of space groups (SG)-6 through space group (SG)-15, or space group (SG)-83 through space group (SG)-88. Candidates include As₂W, As₃W₂, As₂Mo, As₃Mo₂ in space group (SG)-12 and Ti₅Te₄, Ti₅Se₄ in space group (SG)-87, in addition to Ni₄W and Ni₄Mo.The device is configured such that a current through the current channel applies a spin-orbit torque that sets the magnetization state of the free layer.

In some examples, the disclosure is directed to a device which includes a free layer and a current channel. The free layer has a configurable magnetization state. The current channel includes a low-symmetry crystal defining a current channel comprising a low-symmetry crystal defining a point group, wherein the point group is 4/m. The device is configured such that a current through the current channel applies a spin-orbit torque that sets the magnetization state of the free layer.

In some examples, the disclosure is directed to a device which includes a free layer having a configurable magnetization state and defining a film plane. The device also includes a contact layer which includes a low-symmetry crystal with only one mirror plane having relatively large unconventional Spin Hall Effect (SHE). A current applied perpendicular to the film plane applies a spin-orbit torque that sets the magnetization state of the free layer.

The details of one or more examples are set forth in the accompanying drawings and the description below. Other features, objects, and advantages will be apparent from the description and drawings, and from the claims.

### BRIEF DESCRIPTION OF DRAWINGS

FIG. 1A is a schematic cross-sectional diagram of an example MTJ-based spin transfer torque (STT)-MRAM unit in which both the read and write currents are injected vertically through the device by two terminals.

FIG. 1B is a schematic cross-sectional diagram of an example spin-orbit torque (SOT) device, in which the write current is injected in the non-magnetic (NM) layer to manipulate the magnetization of the ferromagnetic (FM) layer.

FIG. 1C is a schematic cross-sectional diagram of an example SOT-MRAM unit where the read and write currents are decoupled via three terminals.

FIGS. 2A-2C illustrate three schematic configurations of an example SOT device.

FIGS. 3A and 3B illustrate example portions of an example MTJ from a perspective view with and without symmetry breaking.

FIG. 4A illustrates an example schematic of a NM/FM/oxide structure with lateral asymmetry from a perspective view.

FIG. 4B is a chart illustrating field-free switching of a perpendicular magnetization at room temperature.

FIG. 5A illustrates a schematic view of an FM layer displaying tilted perpendicular magnetic anisotropy (PMA) originating from a wedge shape.

FIG. 5B illustrates a schematic view of example “easy” axis and “hard” axis of an example FM layer with anisotropy slightly tilted toward the x-axis.

FIG. 6A illustrates a schematic of view of an example ferromagnetic/antiferromagnetic (FM/AFM) ((Co/Ni)/PtMn) bilayer where the exchange bias of the AFM causes the perpendicular magnetization of the FM to tilt toward the x-axis.

FIG. 6B illustrates a schematic side view of an example block interlayer exchange coupling between two CoFe layers via an Ru spacer layer.

FIG. 6C illustrates a schematic cross-sectional view of an example structure using stray field from a biasing layer with in-plane magnetization to realize field-free switching.

FIG. 7A illustrates an example NM/FM bilayer structure and the spin polarization has an in-plane and out-of-plane (OOP) components.

FIG. 7B is a chart illustrating the calculation of switching current density for a perpendicular magnet as a function of η. An external field of 300 Oe is applied only when η is O.

FIG. 8A illustrates the crystal structure of an example crystal of tungsten ditelluride, WTe₂, from a schematic side view. Only one mirror symmetry in the b-c plane exists.

FIG. 8B is a schematic side view of a WTe₂/Py bilayer system.

FIG. 8C is a chart illustrating the angular dependence ST-FMR for WTe₂/Py bilayer when the charge current is applied along the a-axis.

FIG. 9A is a schematic top view of the non-collinear AFM Mn₃GaN with the spin orientation illustrated.

FIG. 9B illustrates the crystal structure of the non-collinear AFM Mn₃Sn on the left, and the right panel illustrates the two types of magnetic alignments of the Mn atoms, denoted as AFM1 and AFM2.

FIG. 9C illustrates the crystal structure of the collinear AFM Mn₂Au and the magnetic moments of Mn atoms are shown, where the (103) plane is shaded.

FIG. 9D illustrates that in Mn₂Au (103), OOP spins are generated when the charge current J is parallel with magnetic moment direction (left two panels). OOP spins vanish when J is orthogonal to moment direction (right two panels).

FIG. 10A illustrates the crystal structure of CuPt (CoPt) with a three-fold rotation symmetry.

FIG. 10B is a chart illustrating that the current direction dependence of magnetization switching shows a period of 120°.

FIG. 10C is a chart illustrating the Hall resistance loop with the applied current of different directions.

FIG. 11A schematically illustrates the crystal structure of Ni₄W from a perspective view.

FIG. 11B schematically illustrates the crystal structure of Ni₄W (100) from a top view with only one mirror symmetry in the a-b plane.

FIG. 11C illustrates a schematic top view of the crystal structure of Ni₄W (211), where the new in-plane axes a′ and b′ are denoted by red arrows.

FIG. 12 is a chart illustrating the power consumption of a spin source/FM bilayer device for different spin-source materials.

FIG. 13 is a schematic diagram of an example two-terminal magnetic random access memory device according to the present disclosure.

FIG. 14 is a chart illustrating an X-Ray diffraction (XRD) pattern of a Ni₄W/CoFeB sample. Inset is a two-dimension XRD pattern showing the large-intensity and concentrated dot-like peak of Ni₄W.

FIG. 15 is a reciprocal space mapping of a Ni₄W/CoFeB sample.

FIG. 16 is a STEM image of an Ni₄W/CoFeB sample. The Ni₄W layer shows a highly-oriented lattice and the CoFeB layer is amorphous.

FIG. 17 is a flowchart illustrating an example technique for forming a device according to the present disclosure.

### DETAILED DESCRIPTION

Spin-orbit torque (SOT) has been intensively studied to control the magnetization of magnetic materials for efficient and ultrafast spintronic devices. Applications based on SOT include the non-volatile magnetic random-access memory (MRAM) and spin logic devices, both of which have the information stored by the magnetization of the magnetic materials. Storage of information is not required for all examples of spintronic devices described in this disclosure, and storage of information is provided simply to ease description.

Materials with perpendicular magnetization, for spintronic devices, may be preferred due to better scalability and lower energy consumption compared to those with in-plane magnetization. However, for conventional spin-source materials, an external magnetic field is required to break the symmetry for the deterministic switching of the perpendicular magnetization. Field-free switching of a perpendicular magnetization is attractive for potential benefits including reduced power consumption.

One potential approach to provide for field-free switching in a device is by including low-symmetry crystal materials, specifically low-symmetry crystal materials with only one mirror plane. These materials may generate out-of-plane (OOP) spins, which can switch the perpendicular magnetization efficiently without external field. Example low symmetry crystal materials include Ni₄W and Ni₄Mo, which may provide advantages including reduced power consumption and/or increased speed when used as a spin-source material, such as, for example, a current channel in an SOT-MRAM device.

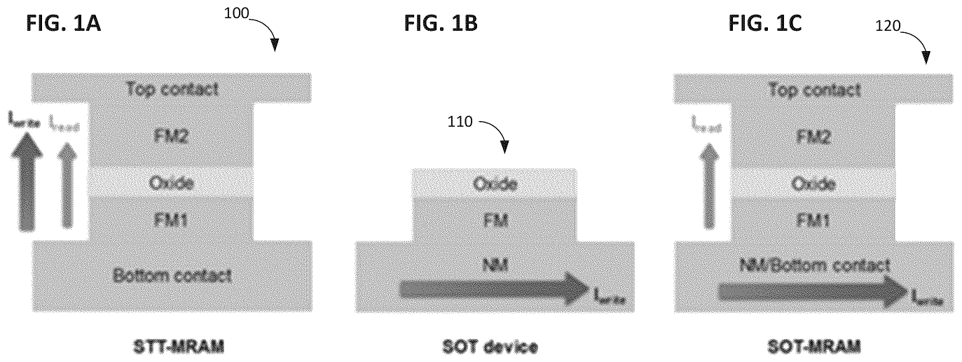

A magnetic tunnel junction (MTJ) with two ferromagnetic layers (FMs) separated by an oxide layer (sometimes called barrier layer) is the building block for magnetic random-access memory (MRAM) and spin logic devices. Examples of the two FMs includes a fixed layer, having a fixed magnetization state, and a free layer, having a configurable magnetization state. The relative magnetization orientations of the two FMs represent the information stored in the MTJ. As there is a drastic difference of the resistance between parallel and anti-parallel states of the magnetic moments due to tunnel magnetoresistance (TMR), the information stored in the MTJ can be read by injecting a read current and measuring the resistance. In order to write the information into the MTJ, the magnetization of one of the two FMs should be switched. Spin-transfer torque (STT) demonstrated in a two-terminal geometry device, where the charge current is injected through the two FMs, as shown in device 100 of FIG. 1A. Electrons flowing through FM2 will be spin polarized, which can change the magnetization of FM1 via STT. This two-terminal structure, however, entails the possibility of unexpected switching of the FM1 by the read current and the resulting errors. To address this problem, another mechanism, spin-orbit torque (SOT), which uses the spin-orbit interaction in the non-magnetic layer (NM), may be employed. As illustrated by device 110 of FIG. 1B, in SOT devices an in-plane write current is injected through the NM, which can be transferred to a spin current flowing into the top FM and manipulate its magnetization. MRAM devices may be built using such SOT devices, as shown by device 120 of FIG. 1C. In SOT-MRAM device 120, the read and write currents are decoupled, and thus, the reliability and endurance may be improved relative to STT-MRAM devices such as device 100. Compared to STT-MRAM, SOT-MRAM has lower power consumption and faster switching. Additionally, voltage control of SOT can be integrated to MTJ devices for logic devices, which are demonstrated to possess reconfigurability and complementary functionality.

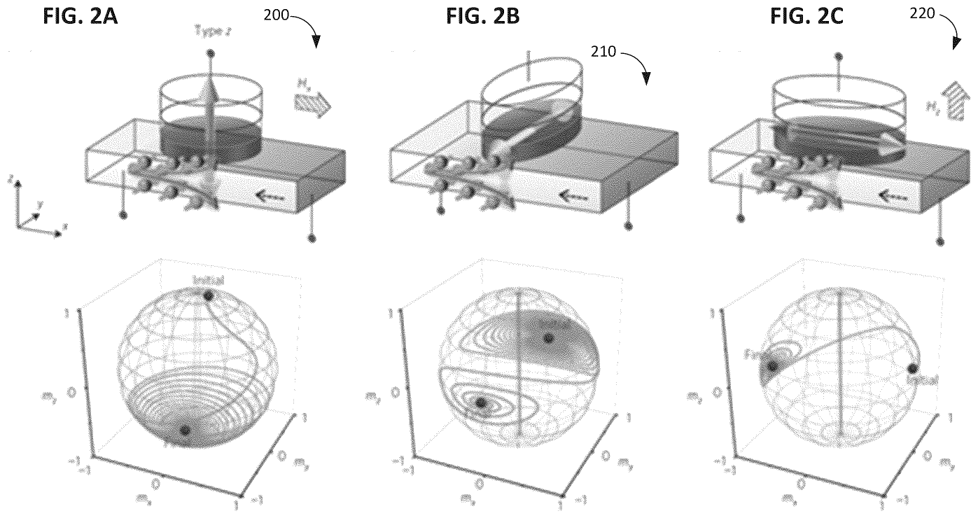

Referring now to FIGS. 2A-2C, FIG. 2A illustrates device 200. Device 200 defines a type z structure, in which the magnetization of the FM layer is out-of-plane. FIG. 2B illustrates device 210. Device 210 defines type y structure, in which the FM layer is has an in-plane easy axis orthogonal to the current flow direction. FIG. 2C illustrates device 220. Device 220 defines type x structure, in which the easy axis of the FM layer is parallel with the current flow direction.

The spin current generation has two origins: the spin Hall effect (SHE) and the Rashba-Edelstein effect. In conventional spin-source materials, such as heavy metals and topological materials, the spin polarization direction σ is perpendicular to both charge current (along x) and spin current (along z) directions and thus is in the plane of the FM layer along y. Such an in-plane spin can only switch an in-plane magnetization in the y direction deterministically, as shown in device 210 of FIG. 2B. This type y configuration, however, may suffer from long precession time before the switching and thus decreases the switching speed. The other two configurations illustrated by device 200 of FIG. 2A and device 220 of FIG. 2C enable fast switching due to less precession. For memory applications, a type z configuration that has a magnet with perpendicular magnetic anisotropy (PMA) is preferred compared to in-plane ones, because the type z configuration may have better scalability and higher thermal stability. In order to switch a perpendicular magnetization, an external magnetic field may be required to break the symmetry, which may not be desirable for practical applications.

In order to realize field-free switching of a perpendicular magnetization, several approaches have been proposed, such as asymmetric geometry, tilted anisotropy, exchange bias between antiferromagnet (AFM) and FM or exchange coupling. All of these approaches focus on breaking the symmetry of the system, so that deterministic switching of a magnet with PMA can occur.

As will be described herein below, these other approaches may not be as desirable as devices built according to the present disclosure, which use a material with low-symmetry material as the spin-source material. Low-symmetry materials, such as low-symmetry crystals having only one mirror plane, may intrinsically break the symmetry without inducing any additional layers or sophisticated fabrication for the asymmetry of the material, which is suitable for large-scale production in industry. Furthermore, out-of-plane spins generated by low-symmetry materials can greatly reduce the switching current and the energy consumption. Low-symmetry crystals having only one minor plane, including Ni₄W and Ni₄Mo, may have advantages in terms of power consumption compared to state-of-the-art spin-source materials.

Spin-orbit torque (SOT) exerted on the magnetization of the FM contains two components: damping-like torque (DLT), τ_{DL}˜m×m×σ, and field-like torque (FLT), τ_{FL}˜m×σ, where σ and m are the directions of spin polarization and magnetization, respectively. These two torques can also be represented by two effective fields: H_{DL}=H_{DL} m×σ a and H_{FL}=H_{FL}σ. The high symmetry of conventional spin-source materials, such as heavy metals, such as Pt, W, Ta, or the like, and topological insulators may constrain the spin polarization direction to be orthogonal to both the current and spin current directions. Thus, if the charge current is injected along the x axis through the spin-source material and the spin current flows along the z axis into the FM, the polarization direction σ is along the y axis.

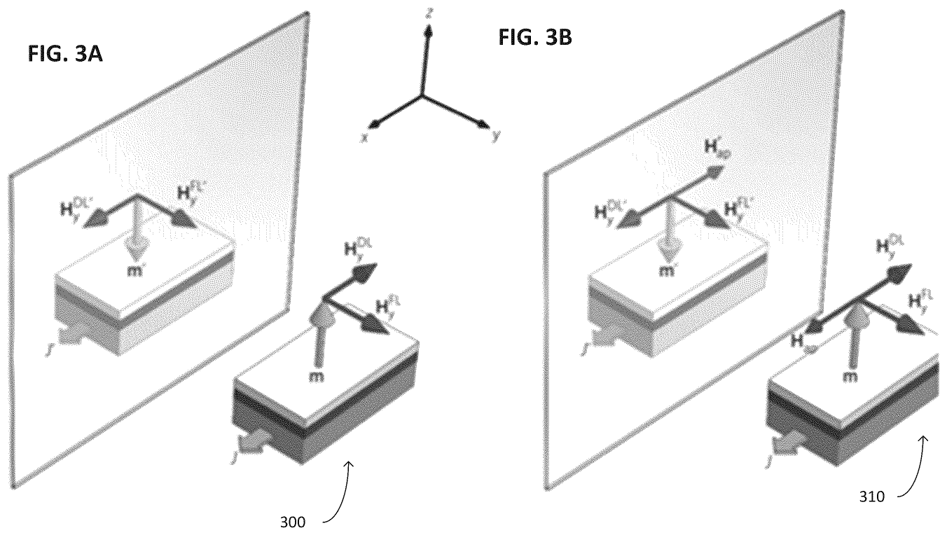

Referring to FIGS. 3A and 3B, FIG. 3A illustrates example device 300. Device 300 defines an NM/FM heterostructure with a x-z mirror plane. The effective fields H_{DL} and H_{FL} preserve the minor symmetry. For the same charge current direction, both up and down states of the magnetization are allowed, indicating non-deterministic switching. FIG. 3B illustrates example device 310. Device 310 defines NM/FM heterostructure under an external magnetic field Hₐₚ, which breaks the minor symmetry of the x-z plane. Fixing the direction of the external field along the x axis will break the symmetry and select the up state for a charge current along the x axis. Thus, deterministic switching of the perpendicular magnetization can be realized.

Symmetry analysis of the NM/FM heterostructure may assist in explaining the requirements of deterministic switching. As shown in FIG. 3A, the heterostructure of a high-symmetry NM and a FM is symmetric with respect to the x-z plane. The structure at the right side of the minor is the original, while the one at the left is its minor reflection. The charge current J is assumed to be disposed along the x axis, and therefore, its minor reflection is also along the x axis. In contrast, the mirror reflection of the perpendicular magnetization m is reversed due to its pseudo-vector property. Since the current direction is the same, the spin polarization direction should also be the same for the original and reflective structure, which is assumed to be along the y axis. The orientation of the effective fields are shown by blue arrows calculated by H_{DL}=H_{DL} m×σ and H_{FL}=H_{FL}σ. One can find that the reflection of the two fields preserves the x-z mirror symmetry (note that magnetic fields are also pseudo-vectors). Therefore, in a NM/FM structure with x-z minor plane, magnetic moments with both up and down orientations are allowed, which suggests that deterministic switching cannot be achieved. One solution for deterministic switching may be breaking the mirror symmetry, as illustrated in FIG. 3B, where an external magnetic field Hₐₚ is applied. If Hₐₚ is along the x axis in the original structure, its reflection about x-z plane should be along the −x axis. Fixing the external field direction can thus break the mirror symmetry and select only one state of the magnetization (up state for Hap along the x axis). Therefore, deterministic switching is realized by symmetry breaking using an external field.

As discussed hereinabove, symmetry breaking is necessary for deterministic switching of a perpendicular magnetization, which is commonly achieved by applying an external field. However, such an external field may not be desirable for memory applications as it may reduce the thermal stability of the perpendicular bit. In order to realize field-free switching of a magnet with PMA, different approaches have been proposed. Below, several techniques for field-free switching are discussed, with a focus on strategies to break the symmetry of the system.

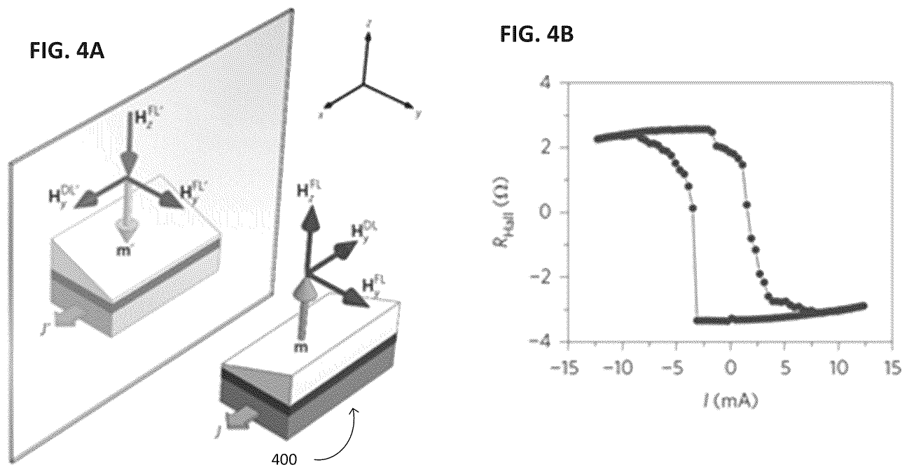

One way to break the minor symmetry may be to create asymmetry of the structure, which can be obtained by growing a wedge-shaped oxide layer on top of the NM/FM heterostructure. As shown in FIG. 4A, device 400 includes an oxide layer with lateral asymmetry along y is deposited on top of the NM/FM heterostructure and breaks the x-z mirror symmetry. A new perpendicular effective field (H_{z}^{FL}) is generated due to the broken symmetry, which favors only one magnetization state for a current direction and enables deterministic switching without external field. In addition to the DL and FL effective fields which also exist in symmetric structures, a new perpendicular effective field H_{z}^{FL} is introduced due to the asymmetry of the structure which only favors one magnetization state. In some examples, in the reflection structure, the current direction is also reversed considering the wedge-shaped oxide layer, thus deterministically correlates one magnetization state to one current direction and facilitates deterministic switching. In some cases, the magnitude of the perpendicular effective field may be proportional to variation rate of the PMA along the y direction, which corresponds to the degree of symmetry-breaking.

The field-free switching may be demonstrated at room temperature by measuring the Hall resistance when sweeping the injected current, as illustrated in FIG. 4B. In some examples, geometric asymmetry of the structure may be generated by other portions of the structure. For example, asymmetric FM layer(s), spin-source layer(s), and/or insertion layer(s) may also be used to induce structure asymmetry, so that the perpendicular effective field H_{z}^{FL} can deterministically switch the magnet with PMA without an external field. Asymmetric structure methods utilize the perpendicular effective field H_{z}^{FL} due to the lateral asymmetry for field-free switching. Besides, tilted anisotropy of the FM layer has been proposed to realize field-free switching.

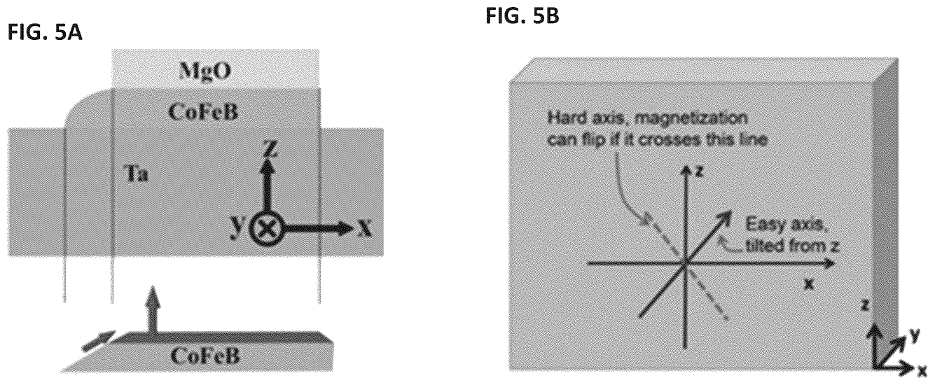

In some examples, as illustrated in FIG. 5A, a ferromagnetic CoFeB layer may be fabricated with a wedge at its edge without the MgO covering, where magnetization is all along its edge. This makes the overall magnetization slightly tilted away from perpendicular direction (z axis). The tilted magnetization may break the mirror symmetry of the y-z plane. Suppose the magnetization is in (+x, +z) quadrature in the original structure, as illustrated in FIG. 5B, then its mirror reflection about y-z plane is in (+x, −z) quadrature, which is not the reversal of the original magnetization. Therefore, when a charge current is injected along the y axis, deterministic switching is expected. Moreover, the influence of possible H_{z}^{FL} for deterministic switching may be lower than the influence of the DLT, and the main contribution may be the DLT. Although field-free switching is realized in asymmetric structures, as discussed above, inhomogeneous magnetic and electrical properties of these asymmetric structures may not be desirable for wafer scale production which may be the obstacle for real applications. That is, because asymmetric structures may not be consistently and inexpensively manufactured at scale, asymmetric structures may not be used in many devices (e.g., SOT-MRAM devices).

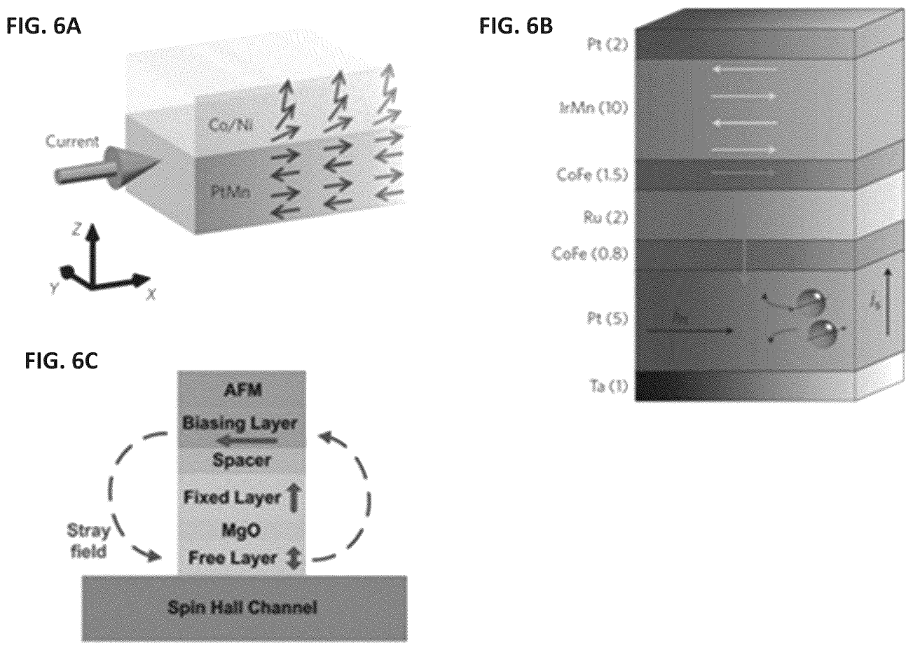

One way to potentially overcome the challenges associated with asymmetric structures involves a device which is symmetric in structure, but includes interfacing an FM layer with an AFM, inducing an exchange bias, and producing an in-plane magnetic field which can break the symmetry of the system. As shown in FIG. 6A at the interface of a FM and an AFM, exchange bias originated from the AFM will produce an effective in-plane field on the magnetization of the FM and tilt it toward the X axis. Such an in-plane effective field breaks the symmetry and deterministic switching is allowed. Indeed, field-free switching without external field may be possible as the antiferromagnetic PtMn can also generate SOT. The Hall resistance switching loop vanishes when an external field of −10 mT is applied, indicating the existence of the exchange bias.

A composite FM CoFeB/Gd/CoFeB with good PMA and reduced saturation magnetization may be used together with PtMn to demonstrate field-free switching. Antiferromagnetic IrMn can also provide exchange bias and serve as the spin source for field-free switching. In some examples, Pt may be used as the spin-source layer and IrMn for the exchange bias only. In some examples, the spin generated by Pt can align the magnetization of IrMn and thus control the exchange bias. In addition, voltage gating may be used in IrMn/CoFeB/MgO system to reduce the switching current density, which is attributed to both voltage-controlled SOT and voltage controlled magnetic anisotropy.

Incomplete switching may sometimes be observed in FM/AFM system. In some examples, it is possible that partial switching may be attributed to a weak exchange bias because of insufficient magnetic field strength in the field-annealing process. Another potential reason is that the polycrystalline nature of the sputtered AFM reduces the effectiveness of the switching. Although the spins in the AFM grains are aligned along the field after the field-cooling process, inhomogeneity still exists among grains, which causes different local exchange bias directions. Since switching can occur only when there is sufficient effective field in the current direction, only a portion of the grains where the exchange bias is along the current direction can be switched, thus causes the incomplete switching. Joule heating has also been proposed to be a factor that can reduce the exchange bias and degrade field-free switching.

Besides exchange bias, exchange coupling between two FM layers separated by a spacer layer (e.g., barrier layer) can also provide an in-plane effective field to break the symmetry. FIG. 6B shows the block where the two CoFe layers are separated by a Ru spacer layer. The symmetry for the bottom CoFe layer with PMA is broken and facilitates field-free switching. The interlayer exchange coupling (IEC) between the two FM layers cants the perpendicular magnetization of the bottom CoFe layer toward the in-plane direction and thus breaks the symmetry. Field-free switching is realized in such a block. The Ru spacer layer needs to be relatively thick (>2.0 nm) so that the PMA will not be overwhelmed by the IEC. A weak IEC provided by a Ta spacer can reduce the thickness of the spacer layer to about 0.5 nm but still maintains sufficient IEC for field-free switching.

The disclosed examples regarding exchange coupling between FM and AFM/FM have the challenge of low strength of the coupling. In addition, specific bottom layers are typically required and poses limitation on the choices of SOT materials. To address this issue, it may be possible to use the dipolar field generated by an in-plane FM layer, as shown in FIG. 6C. The dipolar (stray) field from the in-plane CoFeB layer may be larger than the exchange bias field from examples disclosed herein to this point, and meanwhile a good PMA of the perpendicular CoFeB layer may be achieved. Furthermore, in some examples, there may be reduced or no constraints on the spin source materials when using this stray field strategy. Robust field-free switching is demonstrated and shows complete switching behavior.

The examples disclosed above break the symmetry by sophisticated engineering for asymmetric structure or introducing additional magnetic layers. However, both approaches have their drawbacks. The inhomogeneous properties in asymmetric structures are not desirable in wafer scale production. For the latter approach, the effective field to break the symmetry is not strong enough and difficult to control, resulting in incomplete switching.

In accordance with one or more examples described in this disclosure, this disclosure describes examples approaches to field-free switching strategy, that is, to utilize materials with low symmetry (e.g., low-symmetry crystals that have only one mirror plane). Since the symmetry is broken by the spin-source material itself, no additional layers or asymmetry engineering is required. In addition, due to the low symmetry of the material, unconventional SOT is allowed, which can switch the perpendicular magnetization deterministically, and potentially with lower amount of current as compared to other techniques.

Symmetry analysis for spin Hall conductivity tensor shows that out-of-plane (OOP) spin is allowed in certain materials, which can switch perpendicular magnetization deterministically. In order to obtain the unconventional OOP spins, low symmetry is required for the spin-source material. Besides non-magnetic materials with low symmetry, materials with relatively high symmetry but with a magnetic order can also be used to generate OOP spins in some examples. Compared to conventional SHE by which the spin polarization is in-plane, OOP spins may greatly reduce the switching current and thus the power consumption. In addition to the commonly used DLT and FLT, high-order anisotropic torques may also exist, although their magnitudes are typically small and usually ignored. However, anisotropic torque in materials with specific symmetry can help switch the magnet with PMA, which will be briefly discussed below.

Spin Hall effects (SHE) converts the charge current to spin current, the efficiency of which is described by spin Hall conductivity (SHC) tensor. The definition of SHC tensor is:

Jⱼⁱ=σⱼₖⁱEₖ (1)

where J is the spin current, E is the electrical field and a is the SHC. The three indices i, j, k indicate the spin polarization, spin current flow, and charge current flow directions, respectively. In the most general form, the three indices can take one of the x, y, z directions. Thus, there are totally 27 elements of SHC. The index in the SHC element corresponds to the crystal axes of the material, which are labelled as a, b, c hereinafter.

SHC tensor is constrained by the symmetry of the material, i.e., only part of all 27 elements can be non-zero and these non-zero values can also be dependent. An overall relationship between the form of SHC tensor and symmetry is that lower symmetry allows more SHC elements to be non-zero. Table 1 shows the SHC tensor forms for four different symmetries. If the material has no symmetry, the 27 elements of the SHC tensor are non-zero and are all independent. When the symmetry of the materials increases, the number of non-zero elements of SHC tensor decreases, as one can find from top to bottom in Table I. In addition, not all the non-zero values are independent.

TABLE I
Spin Hall conductivity tensor for point group 1, m, 4/m and m3̅m.

| point | | | |
|---|---|---|---|
| group | σ^{x} | σ^{y} | σ^{z} |
| 1 | $( \begin{matrix}σ \text{?} & σ \text{?} & σ \text{?} \\ σ \text{?} & σ \text{?} & σ \text{?} \\ σ \text{?} & σ \text{?} & σ \text{?}\end{matrix} )$ | $( \begin{matrix}σ \text{?} & σ \text{?} & σ \text{?} \\ σ \text{?} & σ \text{?} & σ \text{?} \\ σ \text{?} & σ \text{?} & σ \text{?}\end{matrix} )$ | $( \begin{matrix}σ \text{?} & σ \text{?} & σ \text{?} \\ σ \text{?} & σ \text{?} & σ \text{?} \\ σ \text{?} & σ \text{?} & σ \text{?}\end{matrix} )$ |
| m | $( \begin{matrix}0 & σ \text{?} & 0 \\ σ \text{?} & 0 & σ \text{?} \\ 0 & σ \text{?} & 0\end{matrix} )$ | $( \begin{matrix}σ \text{?} & 0 & σ \text{?} \\ 0 & σ \text{?} & 0 \\ σ \text{?} & 0 & σ \text{?}\end{matrix} )$ | $( \begin{matrix}0 & σ \text{?} & 0 \\ σ \text{?} & 0 & σ \text{?} \\ 0 & σ \text{?} & 0\end{matrix} )$ |
| 4/m | $( \begin{matrix}0 & 0 & σ \text{?} \\ 0 & 0 & - σ \text{?} \\ σ \text{?} & σ \text{?} & 0\end{matrix} )$ | $( \begin{matrix}0 & 0 & σ \text{?} \\ 0 & 0 & σ \text{?} \\ σ \text{?} & σ \text{?} & 0\end{matrix} )$ | $( \begin{matrix}σ \text{?} & σ \text{?} & 0 \\ - σ \text{?} & σ \text{?} & 0 \\ 0 & 0 & σ \text{?}\end{matrix} )$ |
| m3̅m | $( \begin{matrix}0 & 0 & 0 \\ 0 & 0 & σ \text{?} \\ 0 & - σ \text{?} & 0\end{matrix} )$ | $( \begin{matrix}0 & 0 & - σ \text{?} \\ 0 & 0 & 0 \\ σ \text{?} & 0 & 0\end{matrix} )$ | $( \begin{matrix}0 & σ \text{?} & 0 \\ - σ \text{?} & 0 & 0 \\ 0 & 0 & 0\end{matrix} )$ |

$\text{?} \text{indicates text missing or illegible when filed}$

For conventional heavy metal such as Pt and W of cubic structure, the symmetry is high (m3̅m), resulting in only a few non-zero SHC elements, as shown in the last row of Table 1. In these non-zero SHC elements, the three indices represent spin polarization, where spin current flow and charge current flow directions are orthogonal to each other. Although all the six elements read σ_{xy}^{z}, they actually represent different elements. For example, the bottom non-zero element of σ_{xz}^{x} which reads −σ_{xy}^{z} represents σ_{zy}^{x}, as can be found in the corresponding position in the tensor of the first row. The six elements have the same absolute value is because of the symmetry constraint. Nevertheless, since only conventional SHC exists for high-symmetry materials such as Pt, the spin polarization can only be along the b axis of the spin-source material if it is assumed the charge current is injected along an axis and the film normal direction is c. As already been discussed previously, such an in-plane spin cannot break the symmetry of the system and cannot facilitate field-free switching.

Unconventional SHC, which has the same spin flow and spin polarization directions, can convert charge current to an OOP spin. For the point group m, σ_{zy}^{z} exists, indicating that a charge current along b will generate an OOP spin current along c. Note that for the more symmetric point group 4/m, there are also unconventional SHC elements, σ_{xz}^{x} and σ_{yz}^{y}. The spin direction will also be OOP if the charge current is applied in the c axis and that the film normal direction is along a or b axis of the spin-source material, respectively. Such an OOP spin will break the symmetry for perpendicular magnetization and thus facilitate field-free switching.

Materials having crystals of low symmetry may induce OOP spins. In addition to the SHC tensor, other criterion on crystalline structure can also be used for the determination. For example, two conditions of the spin-source materials for generation of OOP spins may be: 1) the crystal has no rotation symmetry about the film normal direction; and/or 2) the crystal has at most one minor or glide plane perpendicular to an in-plane axis. The symmetry may be correlated to the lattice only if the material is non-magnetic, while the magnetic moment on atoms should also be taken into consideration for the symmetry when the material is magnetic. In other words, magnetic materials provide another degree of freedom to manipulate the symmetry, that is, the magnetic order.

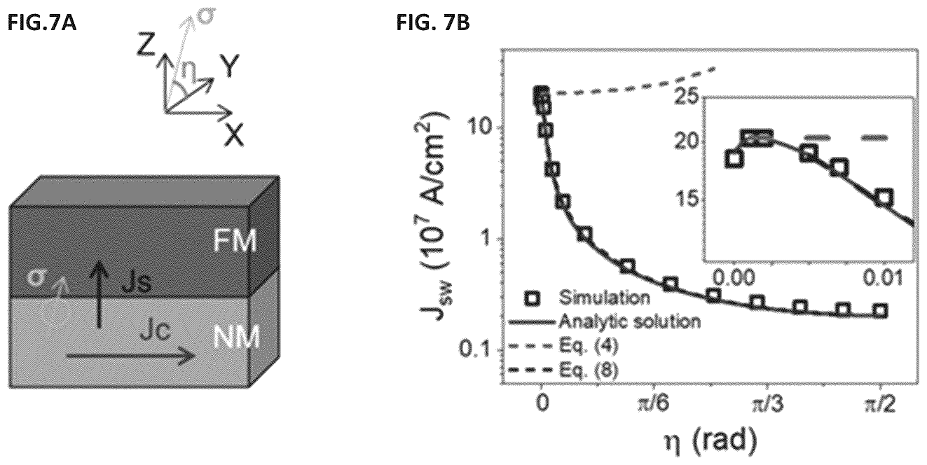

In addition to field-free switching which the in-plane spin associated with conventional SHE cannot realize, OOP spins can also make the switching more efficient. Macrospin simulation based on Landau-Lifschitz-Gilbert (LLG) equation is used to demonstrate this effect. As shown in FIG. 7A, if the spin-source material labelled as NM possesses both conventional and unconventional SHE, meaning that the generated spin will be polarized both in-plane and OOP, the spin polarization should be described by a vector in the Y-Z plane with the associated angle of η. The spin polarization has components along both the y-axis and z-axis with the angle of η. The FM is perpendicularly magnetized. Macrospin simulation of such a bilayer system shows that the switching current density decreases with increasing or equivalently, larger OOP spin polarization component.

The equations of the switching current density can be used to compare quantitatively the efficiency of the OOP spin. If the spin polarization is totally in-plane, i.e., η is 0, the switching current density can be calculated by:

$${J}_{SW} ( η = 0 ) = \frac{{M}_{S} et}{{ℏθ}_{D}} {H}_{K} \qquad ( 2 )$$

where M_{S} is saturation magnetization of the FM layer, t is the thickness of the FM, H_{K} is the anisotropic field, e is the charge of electron, ℏ is the reduced Planck constant and θ_{D} is the DLT efficiency. If the spin polarization has an OOP component and the angle is η, the equation will be:

$${J}_{SW} ( η ) = \frac{2 α}{sin η} \frac{{M}_{S} et}{{ℏθ}_{D}} {H}_{K} \qquad ( 3 )$$

where α is the damping constant of the FM. For the same FM, that is, the same values of M_{S}, t and H_{K}, the switching current density switched by in-plane spins is 1/(2α) larger than OOP spin case. If α=0.02, which is a typical value for CoFeB, the switching current density will be reduced by 25 times. The macrospin simulation is conducted assuming α to be 0.005, and thus the ratio of the switching current between purely in-plane and OOP spins should be 100, as can be calculated by equations (2) and (3), which is consistent with FIG. 7B.

Therefore, OOP spins can greatly reduce the switching current and thus facilitate efficient switching of a perpendicular magnet.

Low-symmetry materials may generate OOP spins for field-free switching, whether the low-symmetry material is magnetic or non-magnetic. For example, non-magnetic materials such as WTe₂ may generate OOP spins. For another example, magnetic materials such as Mn₃Sn and Mn₂Au may generate OOP spins.

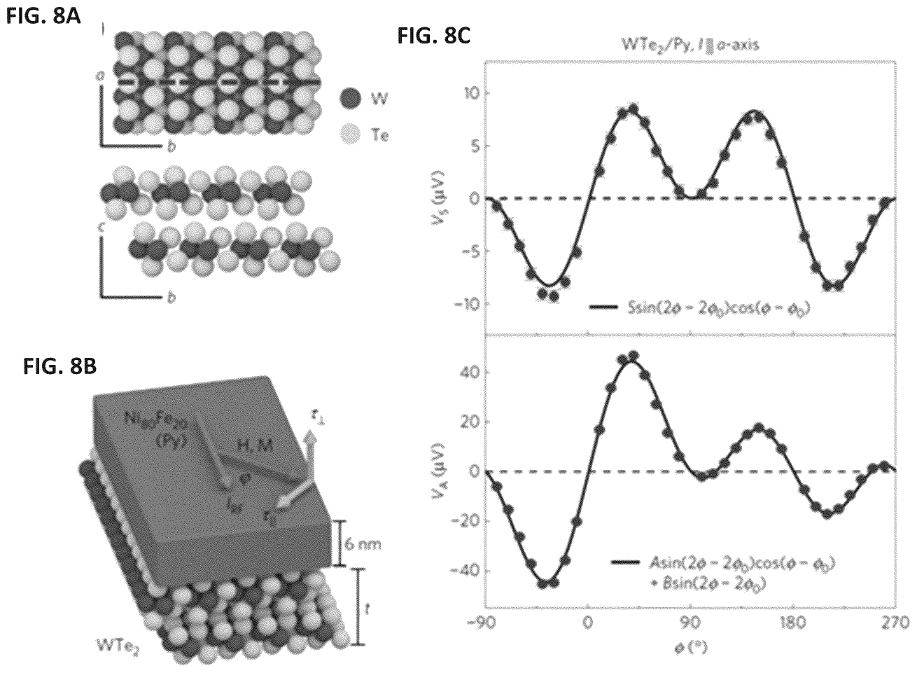

WTe₂ is a layered transition-metal dichalcogenide (TMD) with strong spin-orbit coupling (SOC). Although the bulk crystal of WTe₂ has a relatively high symmetry with the space group of Pmn2₁, the symmetry is reduced to m in the WTe₂/FM bilayer system. FIG. 8A illustrates the crystal structure of WTe₂, where only one minor symmetry in the b-c plane exists and there is not rotation symmetry about the film normal axis, so the crystal may meet the requirement for OOP spin generation, as discussed before. There may be an unconventional SHC component, σ_{zy}^{z}, for the point group of m in Table 1. This means that an OOP spin will be generated if the charge current is applied along the y-axis, or the a-axis for WTe₂ in FIG. 8A.

Referring to FIG. 8B, when a charge current I_{RF} is injected through the sample, in-plane and OOP current-induced torques will drive the magnet moment to process. In order to experimentally demonstrate the existence of the OOP spin, spin-torque ferromagnetic resonance (ST-FMR) may be used. An in-plane magnetized FM layer, Ni₈₀Fe₂₀ (permalloy, Py) is grown on top of the spin-source material WTe₂, as illustrated in FIG. 8B. When a radio-frequency (RF) current I_{RF} is applied, it will be converted to a spin current through SHE and exerts torques on the magnetic moment of the Py, which results in the precession of the moment and an oscillating anisotropic magnetoresistance (AMR). Such a resistance change mixes with I_{RF} and creates a DC voltage Vₘᵢₓ. The Vₘᵢₓ has a symmetric (V_{S}) and antisymmetric (V_{A}) component, corresponding to the in-plane (τ_{∥}) and OOP (τ_{⊥}) torque, respectively.

If the current is injected along the X axis, the spin polarization is along the Y axis for conventional spin-source materials. But for low-symmetry materials, OOP spins along the Z axis and planar spins along the X axis can also exist. Due to the different angular dependence on the magnetization among the DLT and FLT of the three spin orientations, the ST-FMR voltage measured at different field directions can be used to separate different contributions. For the most general case where the spin polarization has components along the X, Y and Z axes, the amplitudes of the symmetric and antisymmetric voltages have the following angular dependence:

V_{S}=S_{DL}^{Y} cos φ sin 2φ+S_{DL}^{X} sin φ sin 2φ+S_{FL}^{Z} sin 2φ (4)

V_{A}=A_{FL}^{Y} cos φ sin 2φ+A_{FL}^{X} sin φ sin 2φ+A_{DL}^{Z} sin 2φ (5)

where DL (FL) indicates the DLT (FLT) and X (Y, Z) indicates the spin polarization direction and φ is the angle between the magnetic field and the applied current, respectively.

For conventional heavy metals such as Pt, spin polarization is along Y axis. Therefore, both V_{S} and V_{A} have the angular dependence of cos φ sin 2φ, per equations (4) and (5). This is indeed the case as the measure may be for the ST-FMR on the Pt/Py sample. For WTe₂ with lower symmetry than Pt, the angular dependence of the ST-FMR signal when the current is applied along the a-axis is different from Pt. With reference to FIG. 8C, a DLT originated from out-of-plane (OOP) spin is demonstrated by the fitting of antisymmetric part (V_{A}). As shown in FIG. 8C, the symmetric part of Vₘᵢₓ (V_{S}) can be fitted by cos φ sin 2φ, which is the same as Pt, suggesting that there is only DLT from spins polarized along the Y axis. However, the antisymmetric part (V_{A}) shows a very different line shape and can only be fitted by adding a sin 2φ term in addition to the conventional cos φ sin 2φ term. This demonstrates the existence of A_{DL}^{Z} in equation (5), which originates from the DLT of OOP spins along the Z axis.

The ST-FMR for a charge current may be performed along the b axis of WTe₂. Since the mirror symmetry is not broken with respect to the b-c plane, OOP spin should not exist. This fact is also supported by the zero value of σ_{zx}^{z} for point group of m in Table 1. Indeed, the V_{A} is back to the angular dependence of cos φ sin 2φ, indicating that there is no OOP spin.

The thickness of WTe₂ may have an impact on the OOP DLT. The sign of the torque may reverse sign between the monolayer and bilayer of WTe₂. This is because the two adjacent layers are related by a 180-degree rotation about the c axis so that the SHC element σ_{zy}^{z} reverses as the current direction is reversed with respect to the crystal. This demonstrates that the unconventional SHE originates from the interface. Furthermore, the field-free switching is realized in the WTe₂/FeGeTe(FGT) bilayer, where FGT is a layered van der Waals ferromagnet and it is attributed to the OOP DLT from WTe₂. In some examples, NbSe₂ may be used as the spin-source material and a FLT originated from OOP spin is detected in certain samples with reduced symmetry by strain.

Besides non-magnetic materials, materials with magnetic orders can also be used as spin sources. Heavy metals and topological materials may be used as spin-source materials due to the strong SOC. Recently, antiferromagnet has been predicted to be able to induce spin polarization, with the magnetic order of either non-collinear or collinear, which has been demonstrated. More importantly, the magnetic order adds an additional degree of freedom to control the symmetry besides the crystal structure. The symmetry can be broken by magnetic moments of the atoms even if the crystallographic symmetry is preserved. As described herein, symmetry which considers the magnetic order is referred to as magnetic symmetry.

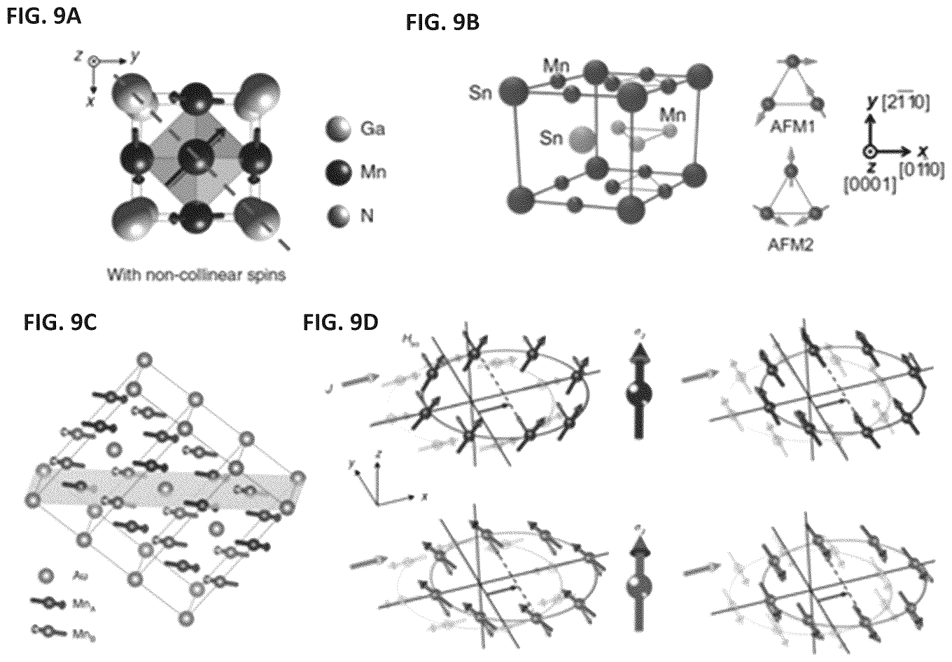

Referring to FIG. 9A, in some examples, only one mirror symmetry in the (110) plane exists, and σ_{zx}^{y}, σ_{zx}^{x} and σ_{zx}^{z} may be measured to be non-zero. Mn₃GaN is a non-collinear AFM, the atomic structure and spin structure of which are shown in FIG. 9A. If the material is non-magnetic, the structure is highly symmetric with a four-fold rotation symmetry and four mirror planes for the (001) plane, which cannot create OOP spin. However, the symmetry is reduced to only one mirror symmetry remaining in the (110) plane if the magnetic order is considered, and this facilitates non-zero unconventional SHC elements and OOP spins. Besides the conventional σ_{zx}^{y}, unconventional elements σ_{zx}^{x} and σ_{zx}^{z} are evaluated to be non-zero by ST-FMR measurements. The unconventional SHC may be due to the magnetic order by conducting experiments at a temperature higher than Néel temperature when the magnetic moments disappear and Mn₃GaN becomes non-magnetic. In some examples, the unconventional SHC elements σ_{zx}^{x} and σ_{zx}^{z} vanish for the non-magnetic state.

In some examples, Mn₃SnN may be used as the spin source, a non-collinear AFM in the same family as Mn₃GaN, i.e., antiperovskite manganese nitrides. In some examples, the existence of the unconventional SHC is correlated to the current direction. When the current direction is parallel to the cluster magnetic octupole moment direction so that the mirror symmetry is broken, unconventional SHC occurs. In contrast, when the current is orthogonal to the cluster magnetic octupole moment direction, there is no unconventional SHC. Field-free switching is demonstrated in the Mn₃SnN/(Co/Pd)₃ system for a current in the symmetry breaking plane, whereas no switching can be achieved if the current is in the plane that preserves the symmetry.

Referring to FIG. 9B, there is one mirror symmetry in the y-z plane for AFM1 and one glide symmetry in the x-z plane for AFM2. Calculations show a non-zero σ_{zx}^{z} and zero σ_{zy}^{z} for AFM1 but a non-zero σ_{zy}^{z} and σ_{zx}^{z} for AFM2. Mn₃Sn is also a non-collinear AFM with two types of magnetic alignments of the Mn atoms, denoted as AFM1 and AFM2, as shown in FIG. 9B. The symmetry for AFM1 and AFM2 is different, as the mirror symmetry is in the y-z plane for AFM1, and a glide symmetry is in the x-z plane for AFM2. In order to obtain the unconventional SHC and OOP spin, the current should be applied in the low-symmetry plane. The calculations agree well with the analysis above, which show a non-zero σ_{zx}^{z} and zero σ_{zy}^{z} for AFM1 but a non-zero σ_{zy}^{z} and zero σ_{zx}^{z} for AFM2 . Unconventional SHC is measured to be non-zero by the hysteresis loop of the anomalous Hall resistance versus the OOP magnetic field, and field-free switching is realized. The switching current is much smaller than Ta as a result of the OOP spin and the associated DLT. In some cases, only partial switching is demonstrated using Mn₃Sn at zero field, which may be attributable to multiple AFM domains with different magnetic alignments and values of σ_{zx}^{z}. A large FLT originated from OOP spins is observed in Mn₃Sn.

While the examples discussed above focus on non-collinear AFMs, in some examples, collinear AFM can also generate OOP spins and realize field-free switching. As shown in FIG. 9C, Mn₂Au has a collinear magnetic order, and may define the (103) texture. Similar to the Mn₃SnN, OOP spins are again related to the current direction with respect to magnetic moment direction. As shown in FIG. 9D, the y-z plane is the mirror plane of Mn2Au (103). OOP spins show up if the current is parallel with the moment direction, or in the low-symmetry plane. In contrast, there is no OOP spin if the current is orthogonal to the moment direction, or in the high-symmetry plane. This effect may be further demonstrated by rotating the magnetic order by 90-degrees and find that the OOP spins appear only when the current is also rotated by 90-degrees. Field-free switching is demonstrated in Mn₂Au/(Co/Pd)₃ stack. In another collinear AFM, RuO₂, OOP spins are also detected.

The DLT and FLT presented previously are isotropic, whose strength is only dependent on the amplitude of the current. However, high-order anisotropic torques also exist for materials with certain symmetry, whose strength is dependent on both the amplitude and direction of the current. These anisotropic torques are usually neglected due to their small values compared to isotropic torques. In some examples, the anisotropic torque of CuPt may realize the field-free switching of CoPt which is a FM, suggesting the potential of such torques for deterministic switching of a perpendicular magnet.

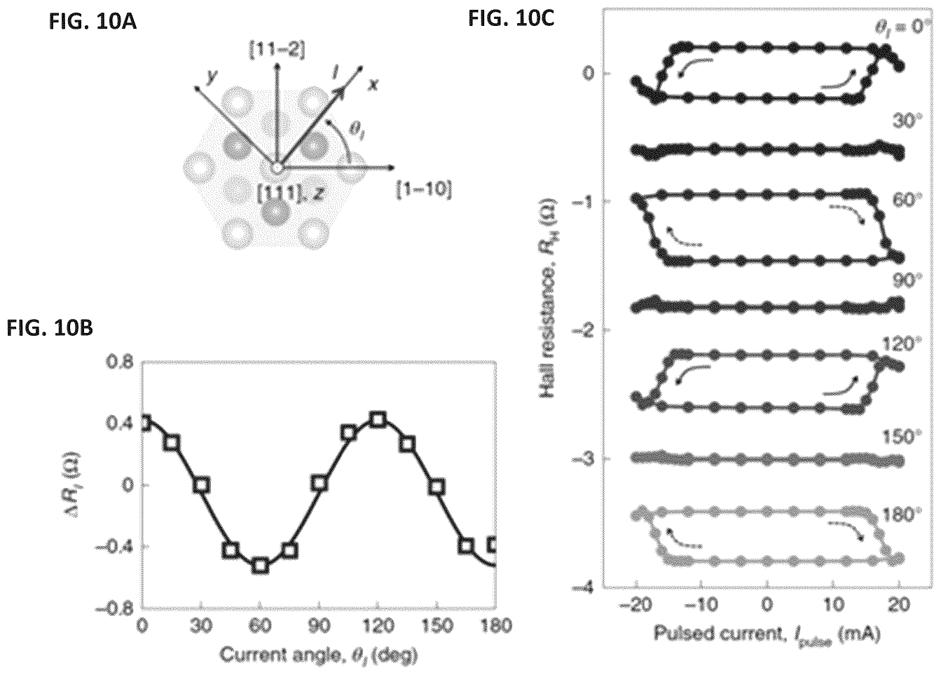

Referring to FIG. 10A, the angle of the applied current relative to [1-10] is defined as θ. As shown in FIG. 10A, CuPt (CoPt) has a three-fold rotation symmetry and one mirror symmetry in the plane orthogonal to [1-10] (θ=90°). The switching of the magnetization is characterized by the anomalous Hall resistance measurement with sweeping current. A period of 120° can be found in the current angle dependence measurement of the switching, as shown in FIG. 10B, with the resistance loops shown in FIG. 10C for different current angles. For θ=0° and 120°, field-free switching is observed. Switching can also occur, but with opposite polarity for θ=60° and 180°. No switching may be found when θ=30°, 90° and 150°. A three-fold symmetry is true of the OOP effective field, which explains the same symmetry of the current direction dependence of the switching. To understand the origin of the OOP effective field which does not exist for conventional spin-source materials, one may analyze the trajectory of the magnetization manipulated by both a DLT and an anisotropic torque. The latter torque may drive the magnetization to OOP direction and is the origin of the OOP effective field, which may facilitate field-free switching.

Using Ni₄W, Ni₄Mo, or both as a spin-source material may generate OOP spins and potentially facilitate field-free switching. Symmetry analysis as discussed above and the SHC tensor form discussed above may prove that unconventional SHC is allowed. Using first-principles calculations, results are shown which are consistent with the theoretical analysis. Finally, based on the SHC values and charge conductivity value, the power consumption of a NM/FM bilayer device using such materials is shown to be reduced relative to other spin-source materials.

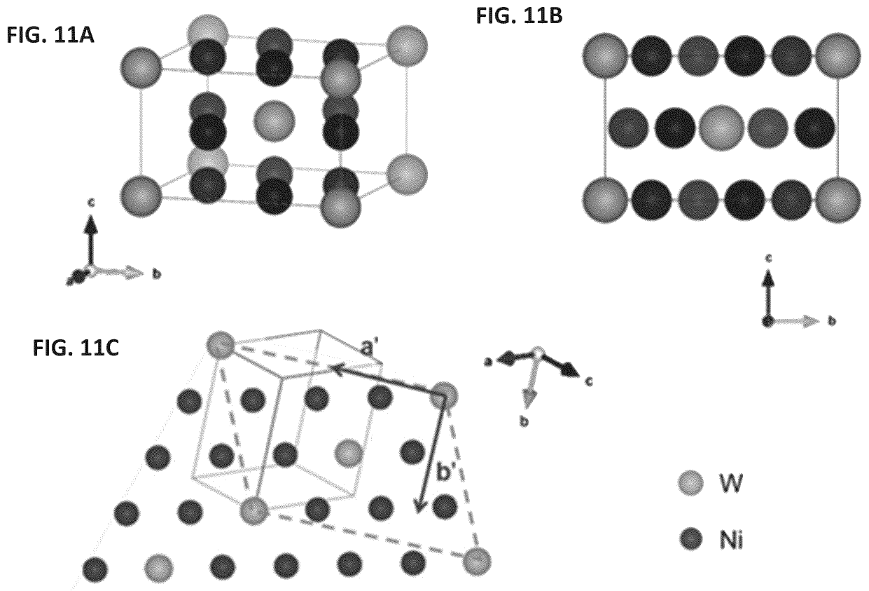

The crystal structure of Ni₄W is shown in FIG. 11A, which has a tetragonal structure. Although the symmetry of this material may be considered relatively high, as there is a four-fold rotation symmetry about the c axis, the (100) or (010) plane of Ni₄W has a low symmetry, which is illustrated in FIG. 11B. For the (100) plane, the a-axis is the OOP direction and b, c axes are in the plane. Only one mirror symmetry exists for this (100) plane, which is in the a-b plane, and no mirror symmetry exists in the a-c plane. Therefore, if the current is applied in the c axis, an OOP spin and the associated effective field is allowed, as explained above.

The existence of the OOP spins may be proven by the SHC tensor. The point group of Ni₄W is 4/m, for which σ_{xz}^{x} and σ_{yz}^{y} are allowed, as displayed in the Table 1, suggesting that an OOP spin exists if the charge current is along c axis of Ni₄W (100) and (010), respectively.

Furthermore, Ni₄W (211) plane also exhibits OOP spins, the in-plane structure of which is shown in FIG. 11C. It has a two-fold rotation symmetry and two different mirror planes for a single layer. However, none of these symmetries exist when considering multiple layers as in the bulk phase. Therefore, OOP spins can still exist for (211)-textured Ni₄W. This may be confirmed quantitatively below by calculation results of the SHC elements.

First-principles calculations were performed to quantify the SHC elements for Ni₄W, with results shown in Table 2. The unconventional SHC element σ_{xz}^{x} is indeed non-zero, with the value of 91.9 ℏ/e(Ωcm)⁻¹. The conventional SHC element σ_{xz}^{x} is 109.6 ℏ/e(Ωcm)⁻¹. The ratio between the unconventional and conventional SHC element is close to 1, indicating a large spin polarization angle η as discussed above, and therefore a low switching current.

TABLE 2
Spin Hall conductivity tensor for Ni₄W (100) and (211) evaluated by
first-principles calculations.

| | σ^{x} | σ^{y} | σ^{z} |
|---|---|---|---|
| general | $( \begin{matrix}{σ}_{xx}^{x} & {σ}_{xy}^{x} & {σ}_{xz}^{x} \\ {σ}_{yx}^{x} & {σ}_{yy}^{x} & {σ}_{yz}^{x} \\ {σ}_{zx}^{x} & {σ}_{zy}^{x} & {σ}_{zz}^{x}\end{matrix} )$ | $( \begin{matrix}{σ}_{xx}^{y} & {σ}_{xy}^{y} & {σ}_{xz}^{y} \\ {σ}_{yx}^{y} & {σ}_{yy}^{y} & {σ}_{yz}^{y} \\ {σ}_{zx}^{y} & {σ}_{zy}^{y} & {σ}_{zz}^{y}\end{matrix} )$ | $( \begin{matrix}{σ}_{xx}^{z} & {σ}_{xy}^{z} & {σ}_{xz}^{z} \\ {σ}_{yx}^{z} & {σ}_{yy}^{z} & {σ}_{yz}^{z} \\ {σ}_{zx}^{z} & {σ}_{zy}^{z} & {σ}_{zz}^{z}\end{matrix} )$ |
| (100) | $( \begin{matrix}0 & 0 & 91.9 \\ 0 & 0 & 109.6 \\ - 74.4 & - 66.4 & 0\end{matrix} )$ | $( \begin{matrix}0 & 0 & - 109.6 \\ 0 & 0 & 91.9 \\ 66.4 & - 74.4 & 0\end{matrix} )$ | $( \begin{matrix}29.7 & 573.6 & 0 \\ - 573.6 & 29.7 & 0 \\ 0 & 0 & - 18.\end{matrix} )$ |
| (211) | $( \begin{matrix}- 6 & - 242 & - 60 \\ 237 & - 26 & 384 \\ 16 & - 385 & 0\end{matrix} )$ | $( \begin{matrix}22 & - 1 & - 114 \\ - 2 & - 10 & 142 \\ 112 & - 128 & - 21\end{matrix} )$ | $( \begin{matrix}2 & 234 & 137 \\ - 271 & 8 & - 189 \\ - 122 & 215 & 15\end{matrix} )$ |

The SHC tensor for Ni₄W (211) was calculated by the mathematical relationships for coordinate transformation and is shown in the Table 2. The axes for the Ni₄W (211) are chosen to be a′=(a, 0, −2c), b′=(−2c², a²+4c², −ac) and c′=(2c, c, a). The in-plane axes a′ and b′ are shown in FIG. 11C. It is assumed that the charge current is applied along the a′ axis, there are both a conventional SHC element σ_{zx}^{y}=112 ℏ/e(Ωcm)⁻¹ and an unconventional element σ_{zx}^{z}=122 ℏ/e(Ωcm)⁻¹. The absolute values of the SHC elements of Ni₄W (211) are larger than the (100) texture, suggesting that (211)-textured Ni₄W is more efficient for charge-to-spin conversion. From the viewpoint of experiments, (211)-textured Ni₄W may be easier to grow since its structure is close packed while (100) is not, which has been grown by sputtering.

OOP spins may be non-zero for both (100) and (211) textured Ni₄W, which can be used for field-free switching, as discussed above. Ni₄Mo, may have a similar structure, and thus may be used and an alternate or in addition to Ni₄W.

As illustrated and discussed above, switching current can be greatly reduced by OOP spins. To further illustrate the benefits of using Ni₄W, the power consumption of Ni₄W may be compared to state-of-the-art spin-source materials for a spin source/FM device.

A parallel-resistor model may be used for the current and power calculations. Shunting effect occurs when the resistivity of the spin source is relatively large compared to the FM, which will cause a waste of current since a large portion of current flows into the FM rather than the spin source which generates the spin current. Therefore, spin-source materials with low resistivity are desired. In order to estimate the switching current for conventional spin-source materials which only have in-plane spins and unconventional materials with OOP spins, equations (2) and (3) may be used, respectively. The thickness of Ni₄W and Ni₄Mo which has the same structure as Ni₄W is 5 nm in the calculation. The FM is assumed to be CoFeB with a damping constant of 0.02.

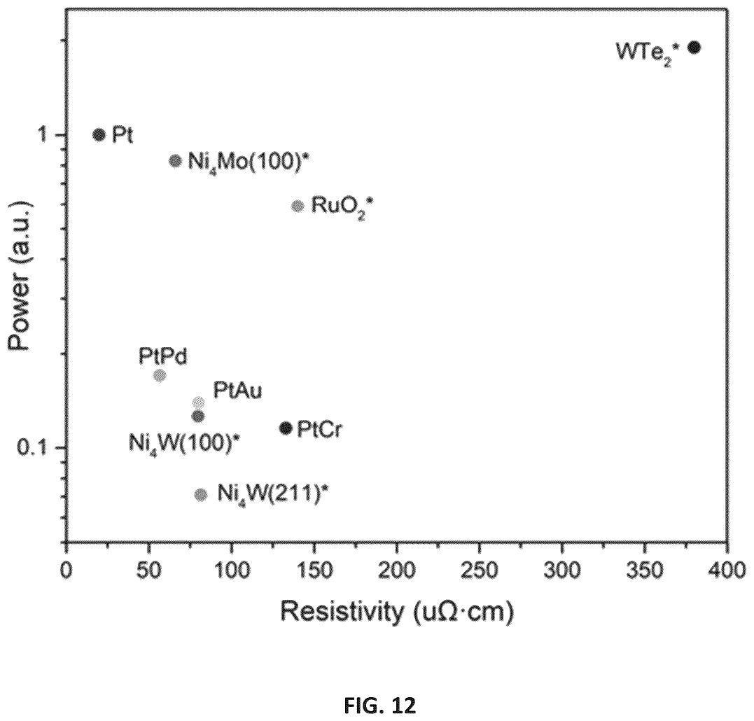

The normalized power consumption results are shown in FIG. 12, where the unconventional materials are labelled by a *. The power consumption axis has the log scale with arbitrary unit normalized by the power consumption of Pt. The thickness of Ni₄W and Ni₄Mo is d=5 nm, and the damping constant of the FM is α=0.02. Materials labelled by * are unconventional ones possessing OOP spins. Compared to heavy metal Pt, the state-of-the-art spin-source materials such as PtAu and PtCr can reduce the power consumption by almost an order of magnitude. Unconventional spin-source materials such as RuO₂ and WTe₂ have the power consumption comparable or smaller than Pt, but are not as efficient for switching as PtAu and PtCr, due to their large resistivity and/or small SHC. Ni₄W and Ni₄Mo have a low resistivity, which is in the same order of magnitude as Pt. Also, the unconventional SHC for OOP spins of Ni₄W is large compared to its conventional SHC, which can greatly reduce the switching current. As a result, the power consumption of Ni₄W is two orders of magnitude lower than Pt and is superior than all the other state-of-the-art materials. (211) textured Ni₄W is better than (100) textured one because of larger values of the SHC. Ni₄Mo is not that efficient in power consumption due to its low ratio between the unconventional and conventional SHC.

As a promising candidate for non-volatile memory applications, SOT-MRAM uses the SOT from the spin-source materials to manipulate the magnetization of the FM. Particularly, MRAM composed of a FM with PMA may provide better scalability and thermal stability, but an external field is required for deterministic switching. In order to switch the perpendicular magnetization without field, several approaches to breaking the symmetry may be employed, including asymmetric structure, tilted anisotropy, exchange bias, interlayer exchange coupling and stray field. Such techniques may cause undesirable effects such as inhomogeneity or incomplete switching.

An example technique to break the symmetry is to use spin-source materials with low symmetry. The broken symmetry intrinsically allows the generation of OOP spins which can greatly reduce the switching current for a perpendicular magnetization. Field-free switching may be provided by using low-symmetry materials as the spin source, including non-magnetic materials with low crystallographic symmetry and magnetic materials with low magnetic symmetry. This disclosure describes Ni₄W as an unconventional spin-source material with a large OOP spin component that facilitates field-free switching. The power consumption of Ni₄W may be two orders of magnitude lower than Pt and may be lower than other materials.

In some examples, a device may include free layer having a configurable magnetization state. The device may include a current channel comprising a low-symmetry crystal with only one mirror plane having relatively large unconventional spin Hall effect (SHE), wherein a current through the current channel applies a spin-orbit torque that sets the magnetization state of the free layer. In some examples, setting the magnetization state of the free layer may include manipulating or modifying the magnitude or direction of the magnetization vector of the free layer. In some examples, the device may be the STT-MRAM device of FIG. 1A, the free layer may be FM1 or FM2. In some examples, the device may be the SOT device of FIG. 1B, the free layer may be FM, and the current channel may be the NM layer. In some examples, the device may be the SOT-MRAM device of FIG. 1C, the free layer may be FM1, and the current channel may be the NM/Bottom contact layer. In some examples, the device may be the SOT-MRAM device of FIG. 1C and the free layer may be FM1. The SOT-MRAM device may further include a fixed layer, which may be FM1, and a barrier layer, which may be the oxide layer. The barrier layer may separate the fixed layer from the free layer, as shown in FIG. 1C. A magnetization state of the fixed layer may not be configurable. The current channel may be the NM/bottom contact layer, and the current channel may be formed from a bulk of the low symmetry crystal. As described herein, a bulk of material is a crystal material that operate based on the properties of the bulk phase of the crystal rather than only on the interface at one surface. Although described with respect to these specific examples, it is considered that low-symmetry crystal materials disclosed herein may be used in other devices. More generally, in some examples, the device may include a spin orbit torque (SOT), spin logic device. The SOT spin logic device may include a free layer and a current channel. The current channel comprising a low-symmetry crystal with only one mirror plane having relatively large unconventional spin Hall effect (SHE), wherein a current through the current channel applies a spin-orbit torque that sets the magnetization state of the free layer

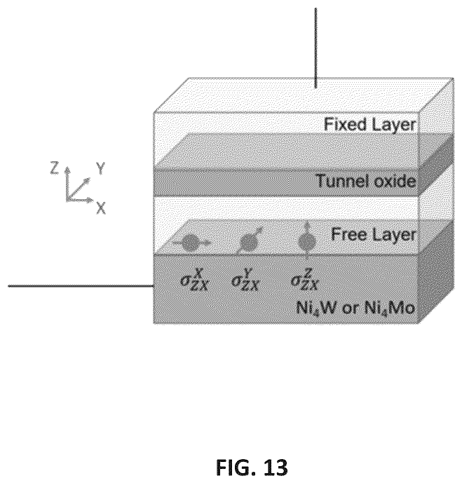

Additionally, or alternatively, the device may, in some examples, be a two-terminal device. FIG. 13 is a schematic diagram illustrating an example two-terminal magnetic random-access memory device according to the present disclosure. Such a device may include a free layer having a configurable magnetization state which defines a film plane that is coplanar with the greatest dimension of the free layer. The device may include a contact layer, which may be similar to the current channel described with respect to FIGS. 1A-1C above. In other words, the contact layer may be a low-symmetry crystal material that has only one mirror plane. A current applied perpendicular to the film plane applies a spin-orbit torque that sets the magnetization state of the free layer. A two-terminal device may include two electrodes, one of which will contact the free layer, and the current or electric field will be applied to this structure perpendicular to the film plane to drive the switching of the free layer. In some examples, low-symmetry crystals having one mirror plane, as described herein, may be added as a layer underneath the free layer of an MTJ, or another two-terminal device. The low-symmetry crystal material may generate large unconventional spin components to switch the free layer through the spin orbit torque effect, alone or together with other effects including STT effects and/or VCMA (voltage-controlled magnetic anisotropy) and VECE (voltage-controlled exchange coupling).

Spin-transfer torque (STT) is a well-studied mechanism that can be used to manipulate the magnetization in a MTJ structure. However, the efficiency of STT is low and a large switching current is usually required. SOT originated from spin Hall effect or Rashba-Edelstein effect has better switching efficiency than STT. But one limitation for SOT-based MRAM is that typical SOT-based devices require three terminals, which makes the scaling of the cell size difficult. To overcome this issue, a two-terminal SOT-MRAM device as illustrated in FIG. 13 may be employed. Such a device may utilize both the high efficiency of SOT and also the simple structure of STT.

Low-symmetry materials may be integrated into the two-terminal MRAM device of FIG. 13. The multi-directional spin polarization generated by low symmetry materials (e.g., Ni₄W, Ni₄Mo, or the like) is expected to be beneficial to the switching of the magnetization of the free layer, either with in-plane or out-of-plane magnetic anisotropy. Specifically, MTJ with magnetic anisotropy in X or Z direction enables faster switching than one with magnetic anisotropy along Y. But both of these two types of devices require external field for deterministic switching. The spins in all X, Y and Z directions generated by Ni₄W or Ni₄Mo will help break the symmetry, which will enable field-free switching. The multi-directional spin polarizations will also induce additional torques to the free layer and further reduce the switching current and power consumption.

In some examples, the bulk of the low-symmetry crystal defines a texture, and the texture may be any one of (211), (100), (010), or (110).

In some examples, the low-symmetry crystal is thermally stable. In this context, thermally stable may mean the low-symmetry crystal is stable enough to work with during manufacturing process associated with devices of the current disclosure (e.g., an SOT-MRAM device). For example, a thermally stable low-symmetry crystal may be amenable to sputtering.

In some examples, the low-symmetry crystal may comprise, consist essentially of, or consist of Ni₄W. In some examples, the low-symmetry crystal may comprise, consist essentially of, or consist of Ni₄Mo. In some examples, the low-symmetry crystal may comprise, consist essentially of, or consist of a mixture or combination of Ni₄W and Ni₄Mo. In some examples, the low-symmetry crystal comprises a dopant. The dopant may be any one or more of Ti, Sc, V, Cr, Mn, Cu, Zn, Fe, Co, Ta, Si, Al, P, B, N, or C. The dopant may be present in elemental form, or as a compound which includes the element. The dopant may be present at any suitable level, such as from about 1 weight percent to about 30 weight percent of the low-symmetry crystal.

In some examples, the current channel may include a plurality of layers including a first layer and a second layer. The first layer may include the low-symmetry crystal. In some examples, the second layer may include the same low-symmetry crystal, a different low-symmetry crystal, or a different type of material altogether. In some examples, the low-symmetry crystal of the first layer may be Ni₄W, and the low-symmetry crystal of the second layer is Ni₄Mo.

In some examples, the low-symmetry crystal may define a point group, and the point group may be 4/m. In some examples, the low-symmetry crystal defines a space group, and the space group is one of space groups (SG)-6 through space group (SG)-15, or space group (SG)-83 through space group (SG)-88. The identified point groups and/or space groups may advantageously balance low-symmetry characteristics to generate OOP spins while maintaining manufacturability and/or thermal stability, providing for manufacturability at scale.

As mentioned above, devices which include a current channel which has a low-symmetry crystal with only one mirror plane may be two-terminal devices or three-terminal devices. Two-terminal devices (FIG. 1A and FIG. 13) may be those devices where the current may directly pass from the SOT material to the free layer and then the barrier and then the fixed layer. Three-terminal devices (FIG. 1C) may be those devices where the charge current flows in the SOT channel (left to right, two-terminal) and the spin current is generated and flow into the free layer (then barrier and fixed layer) through a third terminal.

### EXAMPLES

High-quality Ni₄W film was grown by magnetron sputtering on a sapphire (Al₂O₃) (0001) substrate. A tungsten seed layer with about 3 nm was used on top of sapphire substrate to provide better lattice mismatch. The growth of W seed layer and Ni₄W layer was conducted at 350 C. After cooling down to room temperature, the CoFeB film with in-plane magnetic anisotropy was deposited, capped by Ta layer for oxidation protection.

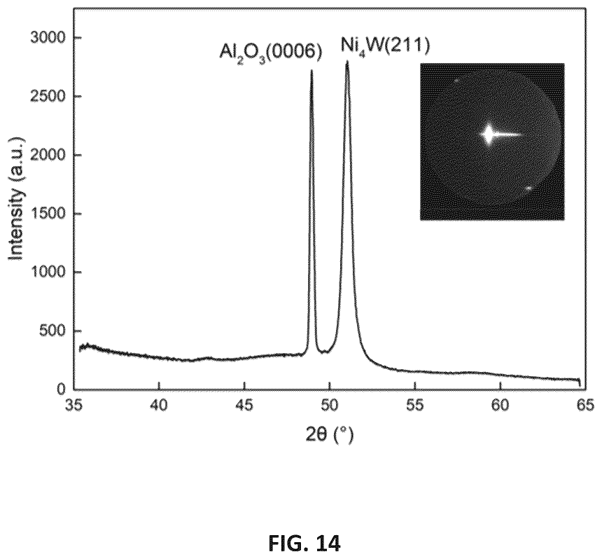

FIG. 14 is a chart illustrating an X-Ray diffraction (XRD) pattern of the Ni₄W/CoFeB sample. Inset is a two-dimension XRD pattern showing the large-intensity and concentrated dot-like peak of Ni₄W. The phase and texture information of the film were measured by X-ray diffraction (XRD) on the sample with the stack of sapphire/W(2.7)/Ni₄W(30)/CoFeB(5)/Ta(3), as shown in FIG. 1. The Ni₄W (211) peak located at 2θ=51° can be clearly seen, with very high intensity. This shows the Ni₄W layer is highly textured. The inset figure shows the two-dimensional XRD pattern. A long bright tail-shape peak is attributed to the thin W seed layer with great texture. The high-intensity dot-shape peak on the left is the Ni₄W peak, indicating the out-of-plane orientation is relatively uniform.

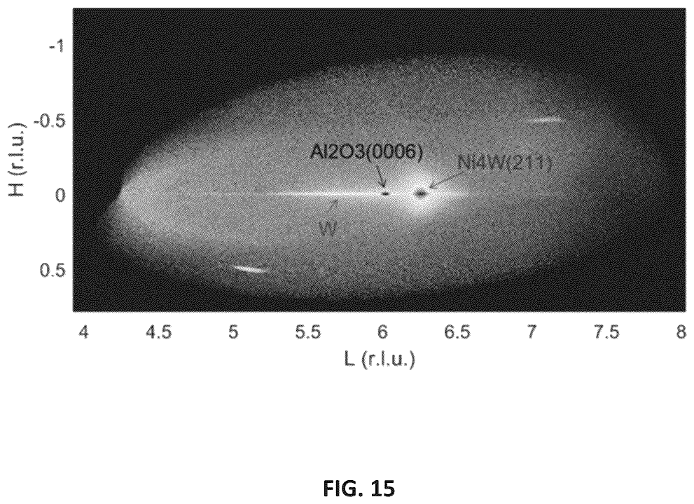

In order to gain more understanding and confirmation of the crystallinity of the Ni₄W layer, a reciprocal space mapping around Al₂O₃ (0006) was performed. FIG. 15 is a reciprocal space mapping of a Ni₄W/CoFeB sample of FIG. 14. As shown in FIG. 15, the Ni₄W (211) peak is clearly illustrated. The width of the diffraction peak is small, which confirms the great crystallinity of the Ni₄W film.

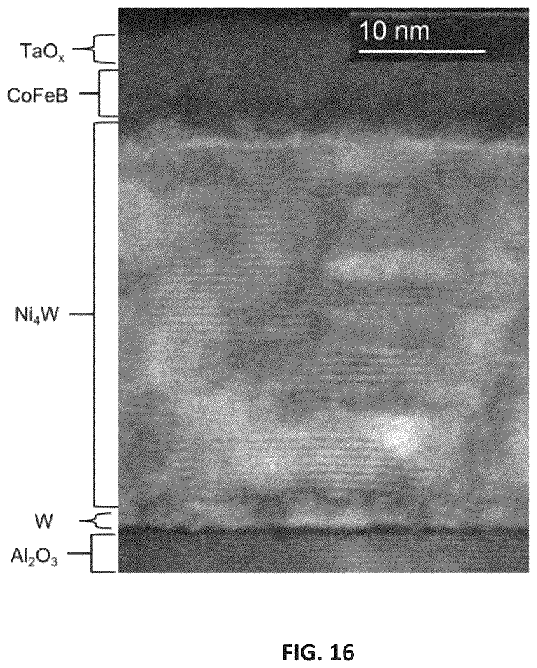

To get a more direct view of the sample microstructure, a scanning transmission electron microscopy (STEM) study was performed on the Ni₄W/CoFeB bilayer sample. FIG. 16 is a STEM image of an Ni₄W/CoFeB sample. The Ni₄W layer shows a highly-oriented lattice and the CoFeB layer is amorphous. The high-angle annular dark-field (HAADF) STEM image of FIG. 16 shows uniform orientation of the Ni₄W lattice. The STEM image of FIG. 16 is consistent with the XRD study, which confirms again the quality of the Ni₄W film that was grown. Ordered lattice cannot be observed in the CoFeB layer, indicating the CoFeB layer is mostly amorphous.

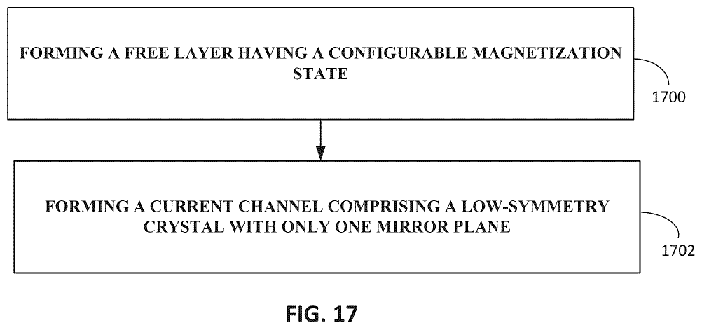

FIG. 17 is a flowchart illustrating an example technique for forming a device according to the present disclosure. The technique of FIG. 17 includes forming a free layer having a configurable magnetization state (1700).

The technique of FIG. 17 also includes forming a current channel comprising a low-symmetry crystal with only one minor plane (1702). The low-symmetry crystal has relatively large unconventional Spin Hall Effect (SHE), wherein a current through the current channel applies a spin-orbit torque that sets the magnetization state of the free layer. In some examples, the current channel is formed from a bulk of the low-symmetry crystal. The bulk of the low-symmetry crystal may define a texture, and the texture may be (211), (100), (010), or (110) for materials with point group of 4/m. In some examples, forming the current channel comprises forming a plurality of layers including a first layer and a second layer, wherein the first layer comprises the low-symmetry crystal. In some examples, the second layer may also include the low symmetry crystal, and the low symmetry crystal may be the same low-symmetry crystal or may be a different low-symmetry crystal. In some examples, the low-symmetry crystal of the first layer may be Ni₄W and the low-symmetry crystal of the second layer may be Ni₄Mo.

In some examples, the low-symmetry crystal may be thermally stable. In some examples, the low-symmetry crystal may be Ni₄W, Ni₄Mo, or a mixture or combination thereof. In some examples, the low-symmetry material may consist of or may consist essentially of Ni₄W, Ni₄Mo, or a mixture or combination thereof. In some examples, the low-symmetry crystal defines a point group, and the point group may be 4/m. In some examples, the low-symmetry crystal may define a space group, and the space group may be one of space groups (SG)-6 through space group (SG)-15, or space group (SG)-83 through space group (SG)-88.

In some examples, the technique of FIG. 17 may further include forming a device comprising a spin orbit torque, magnetoresistive random access memory (SOT-MRAM), wherein the SOT-MRAM comprises the free layer and the current channel.

In some examples, the technique of FIG. 17 may further include forming a fixed layer and forming a barrier layer, wherein the barrier layer separates the fixed layer from the free layer, and wherein a magnetization state of the fixed layer is not configurable. In some examples, the fixed layer, barrier layer, and the free layer may make up a magnetic tunnel junction (MTJ).
Clause 1. A device, comprising: a free layer having a configurable magnetization state; and a current channel comprising a low-symmetry crystal with only one mirror plane having relatively large unconventional spin Hall effect (SHE), wherein a current through the current channel applies a spin-orbit torque that sets the magnetization state of the free layer.
Clause 2. The device of clause 1, wherein the device comprises a spin orbit torque, magnetoresistive random access memory (SOT-MRAM), and wherein the SOT-MRAM comprises the free layer and the current channel.
Clause 3. The device of clause 1, wherein the device comprises a spin orbit torque (SOT), spin logic device, and wherein the SOT spin logic device comprises the free layer and the current channel.
Clause 4. The device of any of clauses 1-3, further comprising a fixed layer and a barrier layer, wherein the barrier layer separates the fixed layer from the free layer, wherein a magnetization state of the fixed layer is not configurable, and wherein the fixed layer, barrier layer, and free layer together form a magnetic tunnel junction (MTJ) device.
Clause 5. The device of any of clause 1-4, wherein the current channel is formed from a bulk of the low-symmetry crystal.
Clause 6. The device of clause 5, wherein the bulk of the low-symmetry crystal defines a texture, and the texture is (211), (100), (010), or (110).
Clause 7. The device of any of clauses 1-6, wherein the low-symmetry crystal is thermally stable.
Clause 8. The device of any of clauses 1-7, wherein the low-symmetry crystal is Ni₄W, Ni₄Mo, or a mixture or combination thereof.
Clause 9. The device of any of clauses 1-8, wherein the low-symmetry material consists essentially of Ni₄W, Ni₄Mo, or a mixture or combination thereof.
Clause 10. The device of any of clauses 1-9, wherein the low-symmetry crystal defines a point group, and the point group is 4/m.
Clause 11. The device of any of clauses 1-10, wherein the low-symmetry crystal defines a space group, and the space group is one of space groups (SG)-6 through space group (SG)-15, or space group (SG)-83 through space group (SG)-88, with examples of As₂W, As₃W₂, As₂Mo, As₃Mo₂ in space group (SG)-12 and Ti₅Te₄, Ti₅Se₄ in space group (SG)-87, in addition to Ni₄W and Ni₄Mo.
Clause 12. The device of any of clauses 1-11, wherein the current channel comprises a plurality of layers including a first layer and a second layer, wherein the first layer comprises the low-symmetry crystal.
Clause 13. The device of clause 12, wherein the second layer comprises the low-symmetry crystal.
Clause 14. The device of clause 13, wherein the low-symmetry crystal of the first layer is different than the low-symmetry crystal of the second layer.
Clause 15. The device of clause 14, wherein the low-symmetry crystal of the first layer is Ni₄W, and wherein the low-symmetry crystal of the second layer is Ni₄Mo.
Clause 16. A method, comprising: forming a free layer having a configurable magnetization state; and forming a current channel comprising a low-symmetry crystal with only one mirror plane having relatively large unconventional Spin Hall Effect (SHE), wherein a current through the current channel applies a spin-orbit torque that sets the magnetization state of the free layer.
Clause 17. The method of clause 16, further comprising forming a device comprising a spin orbit torque, magnetoresistive random access memory (SOT-MRAM), wherein the SOT-MRAM comprises the free layer and the current channel.
Clause 18. The method of any of clauses 16 or 17, further comprising forming a fixed layer and forming a barrier layer, wherein the barrier layer separates the fixed layer from the free layer, wherein a magnetization state of the fixed layer is not configurable, and wherein the fixed layer, barrier layer, and free layer together form a magnetic tunnel junction (MTJ) device.
Clause 19. The method of any of clauses 16-18, wherein the current channel is formed from a bulk of the low-symmetry crystal.
Clause 20. The method of clause 19, wherein the bulk of the low-symmetry crystal defines a texture, and the texture is (211), (100), (010), or (110).
Clause 21. The method of any of clauses 16-20, wherein the low-symmetry crystal is thermally stable.
Clause 22. The method of any of clauses 16-21, wherein the low-symmetry crystal is Ni₄W, Ni₄Mo, or a mixture or combination thereof.
Clause 23. The method of any of clauses 16-22, wherein the low-symmetry material consists essentially of Ni₄W, Ni₄Mo, or a mixture or combination thereof.
Clause 24. The method of any of clauses 16-23, wherein the low-symmetry crystal defines a point group, and the point group is 4/m.
Clause 25. The method of any of clauses 16-24, wherein the low-symmetry crystal defines a space group, and the space group is one of space groups (SG)-6 through space group (SG)-15, or space group (SG)-83 through space group (SG)-88.
Clause 26. The method of any of clauses 16-25, wherein forming the current channel comprises forming a plurality of layers including a first layer and a second layer, wherein the first layer comprises the low-symmetry crystal.
Clause 27. The method of clause 26, wherein the second layer comprises the low-symmetry crystal.
Clause 28. The method of clause 27, wherein the low-symmetry crystal of the first layer is different than the low-symmetry crystal of the second layer.
Clause 29. The method of clause 28, wherein the low-symmetry crystal of the first layer is Ni₄W, and wherein the low-symmetry crystal of the second layer is Ni₄Mo.
Clause 30. A device, comprising: a free layer having a configurable magnetization state; and a current channel comprising a low-symmetry crystal comprising Ni₄W or Ni₄Mo, wherein a current through the current channel applies a spin-orbit torque that sets the magnetization state of the free layer.
Clause 31. The device of clause 30, wherein the low-symmetry crystal comprises a dopant, wherein the dopant comprises any one or more of Ti, Sc, V, Cr, Mn, Cu, Zn, Fe, Co, Ta, Si, Al, P, B, N, or C.
Clause 32. The device of clause 31, wherein the dopant comprises from about 1 weight percent to about 30 weight percent of the low-symmetry crystal.
Clause 33. A spin-orbit torque (SOT) MRAM device comprising a bitcell comprising a tunnel barrier and a current channel layer adjacent to the tunnel barrier, wherein the current channel comprises a low-symmetry crystal with only one mirror plane.
Clause 34. A device, comprising: a free layer having a configurable magnetization state; and a current channel comprising a low-symmetry crystal defining a space group, wherein the space group is one of space groups (SG)-6 through space group (SG)-15, or space group (SG)-83 through space group (SG)-88, and wherein a current through the current channel applies a spin-orbit torque that sets the magnetization state of the free layer.
Clause 35. A device, comprising: a free layer having a configurable magnetization state; and a current channel comprising a low-symmetry crystal defining a point group, wherein the point group is 4/m, and wherein a current through the current channel applies a spin-orbit torque that sets the magnetization state of the free layer.
Clause 36. A device, comprising: a free layer having a configurable magnetization state; and a current channel comprising any combination of features from any of clauses 1, 34, or 35, and wherein a current through the current channel applies a spin-orbit torque that sets the magnetization state of the free layer.
Clause 37. A device, comprising: a free layer having a configurable magnetization state and defining a film plane; and a contact layer comprising any combination of features from any of clauses 1,34, or 35, and wherein a current applied perpendicular to the film plane applies a spin-orbit torque that sets the magnetization state of the free layer.
Clause 38. The device of any of clauses 1-15, wherein the device is a two-terminal SOT device.
Clause 39. The device of any of clauses 1-15, wherein the device is a three-terminal SOT device.
Clause 40. The device of any of clauses 1-15, wherein the device is a memory device, a logic device, a communication device, or any other spin related device which uses the low-symmetry crystal.

1. A device, comprising:
a free layer having a configurable magnetization state; and
a current channel comprising a low-symmetry crystal with only one minor plane having relatively large unconventional spin Hall effect (SHE), wherein a current through the current channel applies a spin-orbit torque that sets the magnetization state of the free layer.

2. The device of claim 1, wherein the device comprises a spin orbit torque, magnetoresistive random access memory (SOT-MRAM), and wherein the SOT-MRAM comprises the free layer and the current channel.

3. The device of claim 1, wherein the device comprises a spin orbit torque (SOT), spin logic device, and wherein the SOT spin logic device comprises the free layer and the current channel.

4. The device of claim 1, further comprising a fixed layer and a barrier layer, wherein the barrier layer separates the fixed layer from the free layer, wherein a magnetization state of the fixed layer is not configurable, and wherein the fixed layer, barrier layer, and free layer together form a magnetic tunnel junction (MTJ) device.

5. The device of claim 1, wherein the current channel is formed from a bulk of the low-symmetry crystal.

6. The device of claim 5, wherein the bulk of the low-symmetry crystal defines a texture, and the texture is (211), (100), (010), or (110).

7. The device of claim 1, wherein the low-symmetry crystal is thermally stable.

8. The device of claim 1, wherein the low-symmetry crystal is Ni₄W, Ni₄Mo, or a mixture or combination thereof.

9. The device of claim 1, wherein the low-symmetry material consists essentially of Ni₄W, Ni₄Mo, or a mixture or combination thereof.

10. The device of claim 1, wherein the low-symmetry crystal defines a point group, and the point group is 4/m.

11. The device of claim 1, wherein the low-symmetry crystal defines a space group, and the space group is one of space groups (SG)-6 through space group (SG)-15, or space group (SG)-83 through space group (SG)-88, with examples of As₂W, As₃W₂, As₂Mo, As₃Mo₂ in space group (SG)-12 and Ti₅Te₄, Ti₅Se₄ in space group (SG)-87, in addition to Ni₄W and Ni₄Mo.

12. The device of claim 1, wherein the current channel comprises a plurality of layers including a first layer and a second layer, wherein the first layer comprises the low-symmetry crystal.

13. The device of claim 12, wherein the second layer comprises the low-symmetry crystal.

14. The device of claim 13, wherein the low-symmetry crystal of the first layer is different than the low-symmetry crystal of the second layer.

15. The device of claim 14, wherein the low-symmetry crystal of the first layer is Ni₄W, and wherein the low-symmetry crystal of the second layer is Ni₄Mo.

16. A method, comprising:
forming a free layer having a configurable magnetization state; and
forming a current channel comprising a low-symmetry crystal with only one mirror plane having relatively large unconventional Spin Hall Effect (SHE), wherein a current through the current channel applies a spin-orbit torque that sets the magnetization state of the free layer.

17. The method of claim 16, further comprising forming a device comprising a spin orbit torque, magnetoresistive random access memory (SOT-MRAM), wherein the SOT-MRAM comprises the free layer and the current channel.

18. The method of claim 16, further comprising forming a fixed layer and forming a barrier layer, wherein the barrier layer separates the fixed layer from the free layer, wherein a magnetization state of the fixed layer is not configurable, and wherein the fixed layer, barrier layer, and free layer together form a magnetic tunnel junction (MTJ) device.

19. The method of claim 16, wherein the current channel is formed from a bulk of the low-symmetry crystal.

20. The method of claim 19, wherein the bulk of the low-symmetry crystal defines a texture, and the texture is (211), (100), (010), or (110).
